(19) United States
(12) Patent Application Publication
(10) Pub. No.: US 2010/0193922 A1
(43) Pub. Date: Aug. 5, 2010

(54) Semiconductor chip package

(75) Inventors: Rainer Kastner, Lauscha (DE); Frank-Michael Doberschutz, Steinheid (DE)

Correspondence Address: DeMont & Breyer, LLC, 100 Commons Way, Ste. 250, Holmdel, NJ, 07733, US

(73) Assignee: ZETEX SEMICONDUCTORS PLC, Lancashire (GB)

(21) Appl. No.: 12/669,151

(22) PCT Filed: Jun. 23, 2008
(86) PCT No.: PCT/GB2008/002163

§ 371 Date: Mar. 18, 2010

(30) Foreign Application Priority Data
Jul. 17, 2007 (GB) 0713791.2

(51) Int. Cl. H01L 23/495; H01L 23/488; H01L 21/60; H01L 21/56

(52) U.S. Cl. 257/676; 257/692; 438/123; 438/124; 257/E21.506; 257/E21.502; 257/E23.031; 257/E23.023

(57) ABSTRACT

A semiconductor chip package is disclosed comprising a semiconductor chip, a lead frame comprising at least one lead, and an encapsulating layer at least partially encapsulating the semiconductor chip and the lead frame. The lead comprises a first portion defining a lead frame pad at least partially exposed at an exterior surface of the package and a second portion extending from the first portion towards the semiconductor chip electrically connecting a surface portion of the semiconductor chip to the lead frame pad. The first portion has a first thickness and the second portion comprises a thinned portion, the thinned portion having a thickness smaller than the first thickness. The lead further comprises a bent portion, and wherein the thinned portion comprises at least part of the bent portion.

### FIELD OF THE INVENTION

The present invention relates to packaging of semiconductor chips. In particular, but not exclusively, the present invention relates to semiconductor chips having a moulded package and specifically leadless surface mounted semiconductor chip packages. A method of fabricating such a semiconductor chip package is also provided.

### BACKGROUND OF THE INVENTION

There is an increasing requirement for semiconductor chip packages having compact structures in order to minimise the space required within consumer appliances. Furthermore, specialist applications, such as mobile telephones, require lightweight, space efficient packaging structures. While there has been a significant reduction in the size and weight of semiconductor chip packages in recent years, there is still a need for further improvements.

There are a large number of known semiconductor chip packaging technologies. Both ceramic and plastic materials have been used to encapsulate, and thereby protect the semiconductor chip, forming a moulded package. Interconnections to the chip from package terminals are commonly provided by wire bonding and/or lead frames.

Wire bonding comprises connecting short lengths of flexible wire between surface portions of the chip and package terminals at the exterior of the package or a lead frame. The wire bonds are then at least partially covered by the encapsulating material to protect them.

A lead frame provides mechanical support to a semiconductor chip during fabrication and portions of the lead frame ultimately electrically connect the chip to package terminals. A portion of the lead frame is internal to the package, i.e. encapsulated by the encapsulating material. Portions of the lead frame may extend externally from the package to electrically connect the package externally and also to allow excess heat within the chip to dissipate. A lead frame may comprise a chip pad, to which the chip is attached and leads which electrically connect the chip to the exterior of the finished chip package. The leads may be either directly connected to the chip, or connected via wire bonds. The chip pad may be exposed at the base of the package. If there is no chip pad then the back of the chip may be exposed to allow direct electrical connections. Exposed chip pads or exposed chip backs are also efficient at transporting heat generated within the chip to the environment, via the substrate to which the chip is attached.

Lead frames are constructed from flat sheet metal by either stamping or etching. Stamping is a mechanical process in which the lead frame structure is formed through a series of stamping/punching steps removing portions of the sheet metal. Etching comprises selectively covering the sheet metal with a resist layer corresponding to the desired pattern of the lead frame and exposing the sheet metal to chemical etchants that remove areas not covered by the resist. Alternative etching techniques known in the art may be used in the fabrication of lead frames. Either the full thickness of the metal sheet, or part of the thickness of the sheet may be etched away. After stamping or etching the lead frame is cleaned and down set. Down setting comprises pushing parts of the lead frame down, relative to adjacent parts of the lead frame such that the down set region can accommodate the chip at the correct height relative to the rest of the lead frame (and in particular the lead pads). This is important in determining whether the back of the chip is exposed at the base of the package.

U.S. Pat. No. 6,143,981 discloses a plastic covered integrated circuit package and a lead frame. U.S. Pat. No. 6,696,747 discloses a metal lead frame for supporting a chip, which is bonded to a central chip pad region of the lead frame. Wire bonds electrically connect pads on the chip to individual leads of the lead frame. The chip, chip pad and the leads are encapsulated by an encapsulating material. The height of the package is minimized by partially etching the chip pad, such that it is reduced in thickness relative to the rest of the lead frame.

Conventional semiconductor chip packages, for instance dual-in-line (DIL) packages, use ceramic or plastic structures with chips wire bonded to lead frames. The main drawback of these conventional designs is the use of leads extending downwardly from the chip package that require plated through holes within a printed circuit board in which the leads are inserted and soldered in place. This is an inefficient use of board space and it is relatively time consuming and expensive to fabricate boards housing such chips.

Flip chip assembly is a method of directly electrically connecting face down (hence “flipped”) electronic components onto substrates, for instance printed circuit boards or lead frames, by means of conductive bumps on the exterior of the chip. Flip chip designs use copper, gold or solder bumps to interconnect the chip to the lead frame. In contrast, wire bonding typically uses face-up chips with a wire connection to each chip terminal. Flip chip assembly eliminates the resistance of the wire bonding. Furthermore, eliminating wire bonds reduces the inductance and capacitance of the connections within the chips and shortens the electrical path length, resulting in higher speed off chip communications and improving the high frequency characteristics of the chip package. Furthermore, wire bond connections are limited to the perimeter of the semiconductor die, which necessitates an increase in the chip size to increase the number of connections. Conversely, flip chip connections can connect to the whole area of the die.

US patent application publication number US 2004/0108580 (Tan et al.) discloses leadless (in the sense of no leads projecting substantially beyond the exterior surface of the package) inverted flip chip semiconductor packaging structures. The structure comprises a semiconductor chip interconnected to a recessed lead frame and the resultant assembly encapsulated in a moulding compound. The final product is a reverse mounted semiconductor chip in a leadless quad flat pack configuration.

Flip chip assembly is a form of surface mount technology in which connections from the chip package to the printed circuit board do not require plated through holes. The external leads of the package are incorporated into the ceramic or plastic body structure. The base of the semiconductor chip may also be exposed at the base of the package, allowing for direct electrical connection to the chip. Portions of the upper surface of the lead frame may also be exposed. This is advantageous as it can allow excess heat to dissipate. Furthermore, eliminating leads exterior to the package significantly reduces the required board area and the package height and weight.

In general, leadless packages, such as flip chip assembled chip packages, are smaller, have better thermal and electrical characteristics than packages with exterior leads and can be more efficiently manufactured. Most chips assembled in leadless packages require only electrical connections on the top of the chip, meaning that flip chip assembly is particularly suitable.

### SUMMARY OF THE INVENTION

It is an object of the present invention to obviate or mitigate one or more of the problems of the prior art, whether identified above or elsewhere. It is a further object of the present invention to provide an alternative form of semiconductor chip packaging.

According to a first aspect of the present invention there is provided a semiconductor chip package comprising: a semiconductor chip; a lead frame comprising at least one lead; and an encapsulating layer at least partially encapsulating the semiconductor chip and the lead frame; wherein the lead comprises a first portion defining a lead frame pad at least partially exposed at an exterior surface of the package and a second portion extending from the first portion towards the semiconductor chip electrically connecting a surface portion of the semiconductor chip to the lead frame pad, and wherein the first portion has a first thickness and the second portion comprises a thinned portion, the thinned portion having a thickness smaller than the first thickness, the lead further comprising a bent portion, and wherein the thinned portion comprises at least part of the bent portion.

Advantageously, the present invention provides a reliable semiconductor device package having a lead frame construction, which results in a very low electrical and thermal resistance. By reducing the thickness of parts of the leads and bending the leads the area and height of the semiconductor chip package can be reduced. Furthermore, the length of the leads is reduced, reducing the resistance of the lead. The partially thinned and bent leads also serve to reduce the incidence of the encapsulating material delaminating from the lead frame. The lead frame is readily adaptable to accommodate different chip thicknesses, without significant redesign of the lead frame.

The thinned portion may comprise a portion of the lead for which the lead is reduced in thickness from one side of the lead. Alternatively, the thinned portion may comprise a portion of the lead for which the lead is reduced in thickness from both sides of the lead.

The bent portion may be entirely within the thinned portion. The lead may only be thinned within the bent portion. The thinned portion may extend from the lead pad.

The junction between the lead pad and the thinned portion may form a step change in the thickness of the lead at the exterior of the package such that the encapsulating layer terminates at the step change adjacent to an exposed part of the lead pad.

The lead may comprise a bend in a first direction and a bend in a second direction, such that the lead frame defines a down set region adapted to accommodate the chip. The lead frame may be thinned in at least part of the down set region.

The leads may not substantially project beyond the exterior of the chip package. Portions of the lead frame may be exposed at the upper surface of the chip package. Preferably, the exposed chip base is coated in a solderable material.

The semiconductor chip package may comprise a plurality of leads. The semiconductor chip package may comprise two or more chips. The or each chip may be fully encapsulated by the resin layer. At least part of the base of the chip or at least one of the chips may be exposed at the base of the chip package.

At least one conductive bump may be provided on the upper surface of the or each chip, and the or each lead is in electrical contact with at least one bump, such that the chip is electrically connected to the lead via the bump.

The or each lead may be electrically connected to the chip by a plurality of bumps.

According to a second aspect of the present invention there is provided a method of fabricating a semiconductor chip package, the method comprising: providing a semiconductor chip; providing a lead frame comprising at least one lead; and encapsulating at least part of the semiconductor chip and at least part of the lead frame within an encapsulating layer; wherein the lead comprises a first portion having a first thickness and defining a lead frame pad at least partially exposed at an exterior surface of the package and a second portion extending from the first portion towards the semiconductor chip and electrically connecting a surface portion of the semiconductor chip to the lead frame pad, and wherein the method further comprises: thinning at least part of the second portion to form a thinned portion such that the thinned portion is thinner than the first portion; and bending at least part of the thinned portion to form at least part of a bent portion of the second portion of the lead.

Thinning at least part of the second portion forming a thinned portion may comprise reducing the thickness of the lead from one side of the lead. Alternatively, thinning at least part of the second portion forming a thinned portion may comprise reducing the thickness of the lead from both sides of the lead.

The method may further comprise only bending the lead within the thinned portion.

The method may further comprise only thinning the lead within the bent portion.

The thinned portion may extend from the lead pad.

The junction between the lead pad and the thinned portion may form a step change in the thickness of the lead at the exterior of the package such that the encapsulating layer terminates at the step change adjacent to an exposed part of the lead pad.

Bending at least part of the lead to form a bent portion may comprise bending the lead in a first direction and bending the lead in a second direction such that the lead frame defines a down set region adapted to accommodate the chip.

The method may further comprise thinning the lead frame within at least part of the down set region.

The leads may not substantially project beyond the exterior of the chip package.

The method may further comprise exposing portions of the lead frame at the upper surface of the chip package.

The method may further comprise providing a plurality of leads. The method may further comprise providing two or more chips.

The method may further comprise encapsulating the or each chip fully within the resin layer.

The method may further comprise exposing at least part of the base of the chip or at least one of the chips at the base of the chip package. The exposed chip base may be coated in a solderable material.

The method may further comprise providing at least one conductive bump on the upper surface of the or each chip, such that the or each lead is in electrical contact with at least one bump, thereby electrically connecting the chip to the lead.

The method may further comprise electrically connecting the or each lead to the chip by a plurality of bumps.

The step of thinning at least part of the second portion forming a thinned portion may comprise partially etching at least part of the second portion to reduce its thickness.

### BRIEF DESCRIPTION OF THE DRAWINGS

The present invention will now be described, by way of example only, with reference to the accompany drawings, in which:

FIG. 1 schematically illustrates a known form of semiconductor chip package;

FIG. 2 schematically illustrates the underside of the semiconductor chip package of FIG. 1;

FIG. 3 schematically illustrates an alternative known form of semiconductor chip package;

FIG. 4 schematically illustrates, in cross section, a semiconductor chip package according to the present invention;

FIG. 5 schematically illustrates in cross section two alternate forms of part of the semiconductor chip package of FIG. 4 during an intermediate stage of fabrication;

FIG. 6 schematically the parts of FIG. 5 after a further intermediate stage of fabrication;

FIG. 7 schematically illustrates, in cross section, part of the semiconductor chip package of FIG. 4, and part of the semiconductor chip package of FIG. 3 allowing them to be compared side by side;

FIG. 8 schematically illustrates a semiconductor chip package in accordance with an alternative embodiment of the present invention;

FIG. 9 schematically illustrates a semiconductor chip package in accordance with yet another alternative embodiment of the present invention;

FIG. 10 schematically illustrates a further embodiment of the present invention, suitable for multi-chip applications;

FIG. 11 schematically illustrates a cross sectional view of the package of FIG. 10; and

FIG. 12 schematically illustrates a further modification of the semiconductor chip package of FIG. 4.

### DETAILED DESCRIPTION

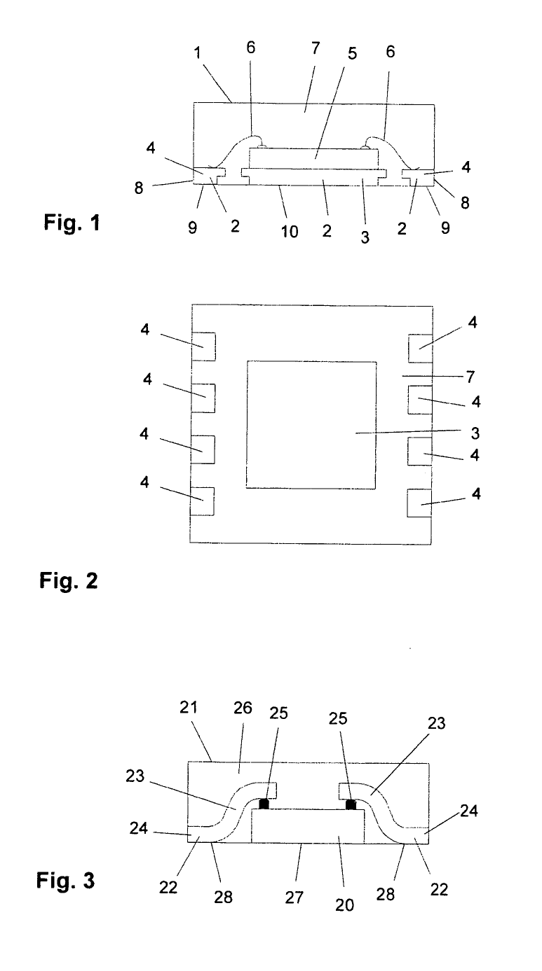

Referring first to FIG. 1, this schematically illustrates, in cross section, a known form of surface mounted leadless semiconductor chip package 1. The chip package 1 comprises a lead frame 2, comprising a chip pad 3 and lead pads 4. A semiconductor chip 5 is attached to the chip pad 3 by an adhesive compound. Surface portions of the semiconductor chip 5 are connected to the lead pads 4 via wire bonds 6. The lead frame 2, chip 5 and wire bonds 6 are encapsulated by a resin layer 7. The term resin layer, as used throughout the description, is intended to refer to any material that partially or fully encapsulates the semiconductor chip and other components. The term is not intended to be restricted to any particular material. Side 8 and base 9 portions of the lead pads 4 and the base 10 of the chip pad 3 are exposed at the exterior of the semiconductor chip package 1 for electrical connection (i.e. the resin layer 7 does not fully surround the chip package 1). The exposed chip pad 2 allows for dissipation of heat from the chip 5. The absence of leads extending externally from the chip package 1 reduces the amount of space taken up by the chip package 1 on a printed circuit board.

FIG. 2 schematically illustrates the underside of the semiconductor chip package 1 of FIG. 1. FIG. 2 illustrates lead pads 4 arranged along two sides of the chip package 1. However, it will be readily apparent that there may be any number of lead pads, for instance the chip may be fully encircled. More generally, lead pads may be provided anywhere across the surface area of the chip.

Referring to FIG. 3, this schematically illustrates in cross section a known form of reverse mounted semiconductor chip 20 in a leadless semiconductor chip package 21. Chip 20 is connected to a lead frame 22 by flip chip bonding. Lead frame 22 comprises leads 23 which extend from the exterior of the chip package 21, where they define lead pads 24, towards the chip 20. It can be seen that lead frame 22 has no chip pad, however one could be provided. Bumps 25 are formed from a conductive material and are provided on the surface of the chip 20. The bumps 25 contact the leads 23 such that the chip is electrically connected to the exterior of the chip package 21. Chip 20 and lead frame 22 are partially encapsulated by resin layer 26. Chip base 27 and side and base portions of the lead pads 24 are exposed on the exterior of the chip package 21.

Leads 23 are of substantially uniform thickness along their whole length. In regions 28 where the leads bend away from the base of the chip package the resin layer forms a thin layer over the leads 23. This thin layer of resin is prone to delaminating from the leads, causing damage to the chip package.

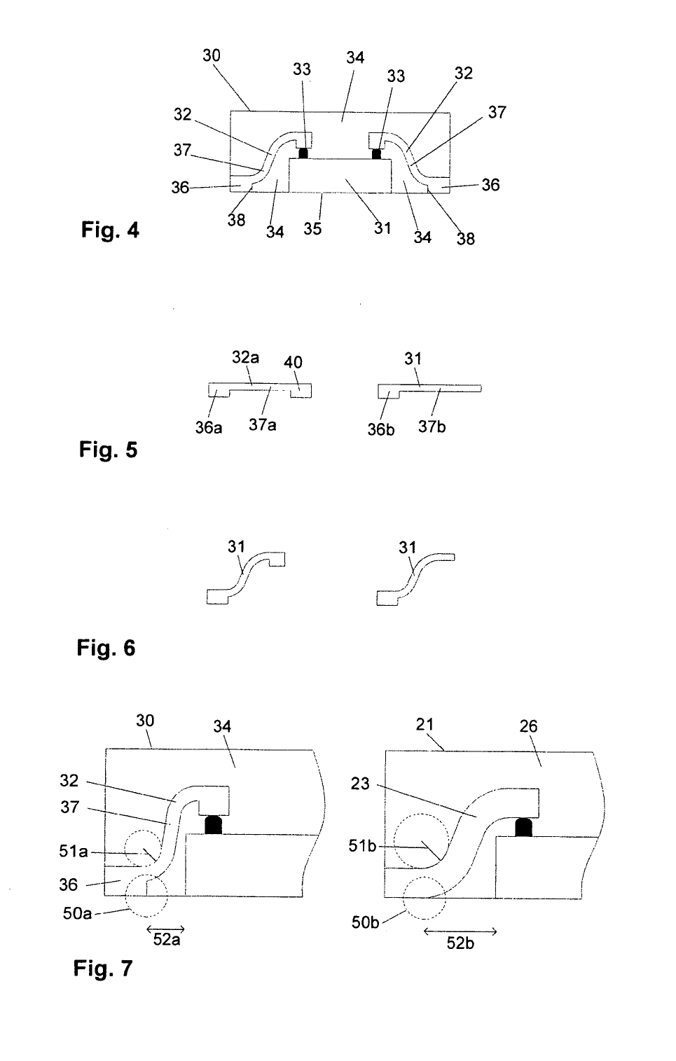

FIG. 4 schematically illustrates, in cross section, a semiconductor chip package 30 according to the present invention. Semiconductor chip 31 is connected to a lead frame, comprising leads 32, by bumps 33 formed from a conductive material. Encapsulating layer 34 (such as a resin layer) partially covers chip 31 and lead frame 32. Base surface 35 of chip 31 is exposed at the exterior of the package 30. Exposed portions of chip 31 may be coated with a solderable material in certain embodiments of the present invention.

Leads 32 comprise first portions 36 defining lead pads which have partially exposed sides and base at the exterior of the package 30. Leads 32 are connected to the bumps 33 such that surface portions of the chip 31 are electrically connected to the lead pads 36. In alternative embodiments of the present invention there may be no conductive bumps 33, such that the leads 32 are in direct contact with the chip 31. Alternatively, leads 32 may be connected to the chip 31 by wire bonds. When viewed from above, chip 31 may be fully surrounded by leads 32, or there may be leads on any number of the sides of the chip. There may be any number of leads on each side of the chip.

Leads 32 further comprise second portions 37. Second portions 37 are thinner than the lead pads 36 and also thinner than the ends of the leads connected to bumps 33. That is, the first portion has a first thickness, measured in the direction of the depth of the package, and the second portion comprises a thinned portion having a thickness smaller than the first thickness. In the cross sectional view shown in FIG. 4, the thickness of the first portion is measured in the vertical direction. Second portions 37 are alternatively referred to herein as thinned portions 37. It will be appreciated that in alternative embodiments of the present invention the ends of the leads connected to the bumps 33 may not be thicker than the thinned portion 37.

Lead frame 32 is formed from sheet metal by etching (or alternatively by stamping or a combination of the two). Portions of the sheet metal may be fully etched such that the metal is completely removed to form the pattern of the lead frame. The thinned portion 37 is formed by half etching the sheet metal such that some of the thickness of the metal is removed. The term half etching is not intended to limit the thinned portion to being exactly half the thickness of the sheet metal (although it may be). The thinned portion 37 is shown as being thinned from one side only, although it may alternatively be thinned from both sides.

The lead frame 32 is down set in the region of chip 31. That is, during fabrication, leads 32 are bent as shown forming an S shaped bend such that the base of lead pads 36 is in approximately the same plane as the base 35 of chip 31. That is, the depth of the cavity formed by the down set region is the same as the thickness of the chip 31 plus the height of bumps 33. In alternative embodiments, the base 35 of the chip 31 could be higher than the base of the lead pads 36 such that the chip is fully encapsulated by the resin layer 34 (i.e. the base 35 of the chip is not exposed). The term “down set” refers to the fact that during fabrication the package is assembled the opposite way up to that show for the finished package in FIG. 4. Chip 31 is placed onto the down set region of the lead frame such that electrical contact is made via bumps 33, before encapsulation by resin layer 34. The term confers no restriction upon the orientation of the chip 31 or the lead frame 32 in the finished package 30. In alternative embodiments of the invention the leads may have more or less bends such that they approach the chip at differing angles.

The total depth of the lead frame 32 is equal to the thickness of the sheet metal from which the lead frame 32 is formed (i.e. the thickness of the leads in the non-thinned regions) plus the degree of bending. It will be appreciated that by altering the degree of bending of the lead frame 32 and/or altering the length of lead between the two bends, chips of varying thickness may be accommodated. This flexibility of the type and dimension of chip that can be accommodated makes the chip package illustrated in FIG. 4 very widely applicable.

As can be seen in FIG. 4, the bent portion of the leads 32 is within the thinned portion 37. By reducing the thickness of the leads 32 where they are to be bent, the radius of the bend or bends can be reduced. Reducing the bending radius significantly reduces the space taken up by the leads 32, reducing the size, and in particular the area, of the finished chip package 30. In alternative embodiments of the present invention there may only be one bend (i.e. a bend in only one direction). The bent portion may be entirely within the thinned portion 37, or alternatively the bent portion may extend beyond the thinned portion 37.

Furthermore, it can be seen in FIG. 4 that the thinned portion 37 of the leads 32 extends up to the edge of the lead pads 36. Consequently at the edge of the exposed base of the lead pads 36 there is a step change 38 in the thickness of the leads 32. This has the advantageous effect of preventing the resin layer from forming a very thin transition zone where it approaches the lead pads 36 (i.e. where the leads 32 curve away from the base of the package 30). Such a thin layer of resin (also known as plastic flash) is disadvantageous as it can cause the resin layer to delaminate from the lead frame 32, damaging the package 30. Step change 38 is additionally advantageous as this locks the leads 32 more closely into the resin layer 34, which increases the overall strength of the chip package 30.

Lead frame 32 can be made from a number of different materials. These are limited only by the requirements that they are electrically conductive and bond well to the resin layer and bumps 33. Typically, the lead frame 32 is formed from a metal such as a copper alloy or an iron-nickel alloy. Exposed portions of the lead frame 32 may be plated with silver, nickel or gold to reduced their resistance.

In certain embodiments of the present invention the package is able to transport a large amount of heat away from the chip 31 through leads 32. The tops of the leads 32 may be exposed at the exterior of the chip package to aid this conduction of heat. Furthermore, the base 35 of the chip may be connected to a printed circuit board cooling area to conduct away excess heat.

The exposed lead pads 36 and the chip back 35 may be plated with a solderable metal or metal layer sandwiched between the package and the printed circuit board before assembly to improve the strength of the solder connection to the printed circuit board.

Referring now to FIG. 5, this schematically illustrates in cross section two alternate forms of the leads 32 during an intermediated stage of fabrication. Leads 32 are depicted after etching, but before being bent into their final down set form. Lead 32a is of a similar form to lead 32 shown in FIG. 4. Lead 32a comprises lead pad portion 36a and thinned portion 37a. The opposite end of lead 32a to the lead pad 36a comprises a second thicker portion 40, at the point where, ultimately, lead 32 is to be attached to bump 33.

Lead 32b is similar to lead 32a, with the exception that there is no second thicker portion. That is, the thinned portion 37b extends from the lead pad 36b to the other end of the lead 32. It will be appreciated that alternative configurations of leads are possible. For instance the thickness of the thinned portion may vary relative to the thickness of the remainder of the lead. Alternatively, the thinned portion 37 may not start next to the lead pad 36. The exemplary leads 32 shown in FIG. 5 have thinned portions approximately half as thick as the remainder of the leads. As discussed above, the leads 32 may be thinned from both sides. The proportion and position of the thinned portion may also vary from the examples shown.

FIG. 6 shows leads 32a and 32b after being bent to form part of a lead frame in a down set region. The leads are shown as being bent in two opposite directions, such that the ends of the leads are in approximately parallel planes. It will be appreciated that in alternative embodiments of the present invention the degree and direction of bending may vary in order to provide appropriate connections between the lead pads 36 and the chip.

Referring now to FIG. 7, this schematically illustrates, in cross section, part of the semiconductor chip package 30 of FIG. 4, and part of the semiconductor chip package 21 of FIG. 3. Chip package 30 is in accordance with the present invention. Chip package 21 is of a known type.

Marked areas 50a, 50b indicate the critical regions for delaminating between the leads 32, 23 and the resin layer 34, 26. For the known chip package 21, the lead frame has leads 23 of a constant thickness throughout their length. This results in a transition zone of resin. In certain embodiments of the present invention the encapsulation material may comprise a resin material containing a predetermined concentration of filler particles. The filler particles influence the mechanical and thermal characteristics of the encapsulation layer. During encapsulation, the resin (containing the filler particles) flow into every gap that is available on the surface of the semiconductor device. If a gap is smaller than the diameter of the filler particles then most of the filler particles will be prevented from entering the gap, such that the gap contains only resin and smaller filler particles. This forms a transition zone of “resin flash”, which has differing mechanical and thermal properties to the rest of the encapsulation layer. This change in the mechanical and thermal properties can leave this regions of an encapsulation layer prone to delamination. Such a narrow gap can occur at area 50b for known forms of semiconductor package. Conversely, for chip package 30 having a thinned portion 37 at the bend extending up to the edge of lead pad 36, there is no resin flash. This results in a mechanically more stable chip package, suffering less from delaminating.

Furthermore, it can be seen that the radius of the bend 51a for the lead with a thinned portion 37 is smaller than the radius of the bend 51b for the lead without a thinned portion. Consequently, the length 52a of the package taken up between the edge of the lead pad and the edge of the chip is smaller for the package having leads with thinned portions than for the corresponding measurement 52b for the conventional chip package 21. This results in a more efficient use of space within the package, and therefore smaller and lighter chip packages.

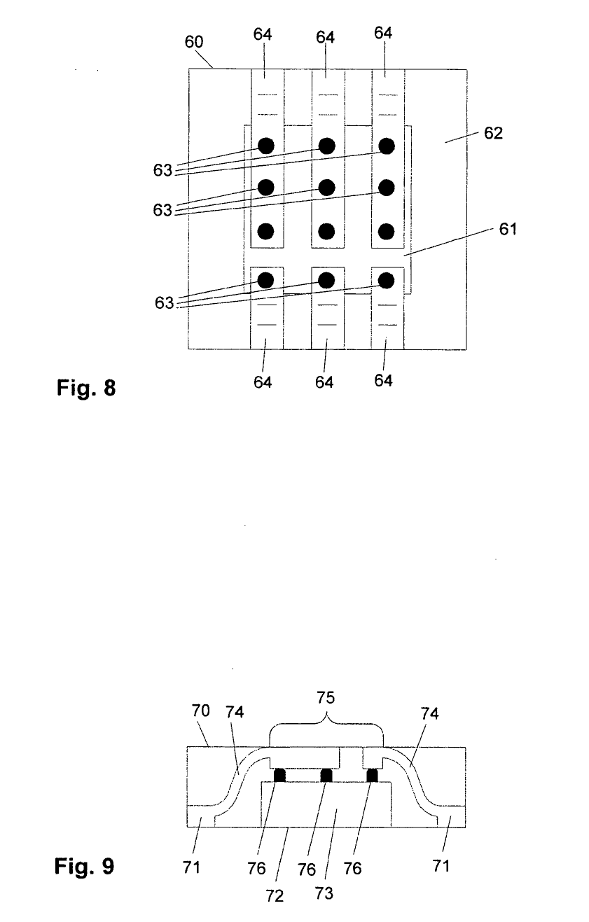

FIG. 8 illustrates an overhead view in partial cross section of a semiconductor chip package 60 in accordance with an alternative embodiment of the present invention. Chip 61 is encapsulated within resin layer 62. Chip 61 has an array of bumps 63 on its upper surface contacting an array of leads 64. Some of leads 64 are shown as connecting to multiple bumps 63, which improves the transfer of heat from chip 61 and the electrical connection of the leads 64 to the chip 61. Leads 64 have thinned and bent portions as for the leads 32 of the chip package shown in FIG. 4.

FIG. 9 illustrates a further modification of the chip package of FIG. 4. In chip package 70 the back and sides of lead pads 71 are exposed as before, as is the base 72 of chip 73 for external connections. However, in addition, parts of leads 74 are exposed in the down set region 75 on the top of the package 70 to improve the transfer of heat from the package. Similarly to the package of FIG. 8, one lead is connected to two bumps 76, while the other lead is connected to a single bump 76.

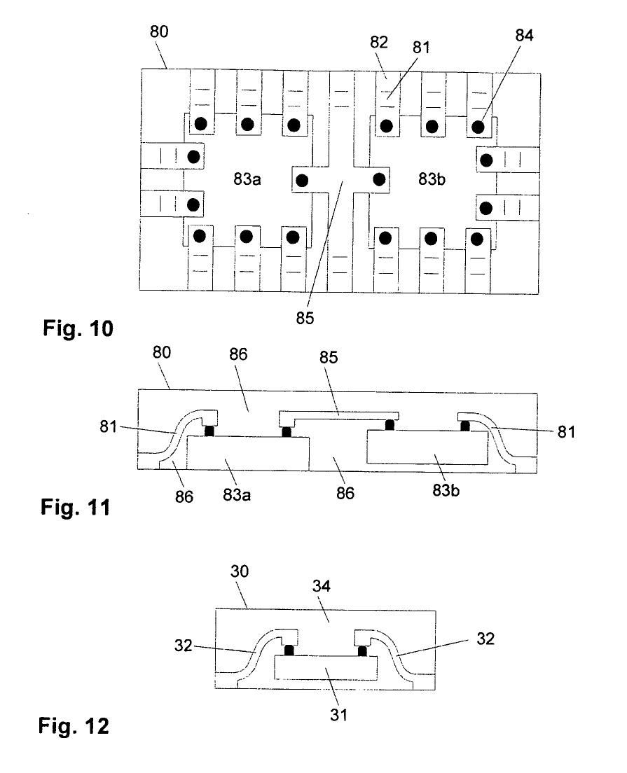

Referring now to FIG. 10, this illustrates a further embodiment of the present invention, suitable for multi-chip applications. Package 80 comprises a plurality of leads 81 each extending from lead pads 82 to one of chips 83a and 83b, contacting bumps 84. Part of the lead frame 85 forms a bridge in the down set region between chips 83a and 83b.

FIG. 11 illustrates a cross sectional view of the package 80 of FIG. 10. It can be seen that the chips are disposed at different levels within the package 80 due to different degrees of etching of the leads 81. Leads 81 in the down set cavity for chip 83b are partially etched, increasing the depth of the cavity, and thereby raising the height of chip 83b in the finished package. The result is that the base of chip 83a is exposed, whereas the base of chip 83b is not exposed (i.e. chip 83b is fully encapsulated by resin layer 86).

FIG. 12 illustrates of modification of the semiconductor chip package 30 of FIG. 4, in which the degree of bending of leads 32 has been altered, such that chip 31 is fully encapsulated within resin layer 34.

The above described embodiments of the present invention all offer the same improvement over the prior art. By reducing the thickness of the leads in the region of the bends the size of the package can be reduced. For chip packages made in accordance with the present invention, a reduction of package area of 10% has been observed. Furthermore, a reduction of package height of 0.5 mm to 0.7 mm has been observed. Connecting the leads to copper bumps gives a significant reduction in resistance, of over 50% compared with comparable chip packages using wire bonding. In certain embodiments of the present invention the thinned portion of the leads extends up to the lead pads at the exterior of the chip reducing resin flash and therefore helping to prevent delaminating.

Improved semiconductor chip packaging in accordance with the present invention is applicable in a wide range of products, including products based on bipolar transistors or UMOS transistors, to provide improved electrical characteristics, including a reduced on-resistance. Furthermore, semiconductor packaging in accordance with the present invention provide an efficient packaging solution for co-packaging of discrete chips. In lighting applications, the reduced package area can provide better power dissipation per unit area. The reduction in inductance provides for improved RF performance, which is particularly advantageous, for instance in Direct Broadcast Satellite amplifiers.

Further modifications and applications of the present invention will be readily apparent to the appropriately skilled person.

1-39. (canceled)

40. A semiconductor chip package comprising:
a semiconductor chip;
a lead frame comprising at least one lead; and
an encapsulating layer at least partially encapsulating the semiconductor chip and the lead frame;
wherein the lead comprises a first portion defining a lead frame pad at least partially exposed at an exterior surface of the package and a second portion extending from the first portion towards the semiconductor chip electrically connecting a surface portion of the semiconductor chip to the lead frame pad, and wherein the first portion has a first thickness and the second portion comprises a thinned portion, the thinned portion having a thickness smaller than the first thickness, the lead further comprising a bent portion, and wherein the thinned portion comprises at least part of the bent portion,
wherein the thinned portion extends from the lead pad,
and wherein the junction between the lead pad and the thinned portion forms a step change in the thickness of the lead at the exterior of the package such that the encapsulating layer terminates at the step change adjacent to an exposed part of the lead pad.

41. The semiconductor chip package according to claim 40, wherein the thinned portion comprises a portion of the lead for which the lead is reduced in thickness from one side of the lead.

42. The semiconductor chip package according to claim 40, wherein the thinned portion comprises a portion of the lead for which the lead is reduced in thickness from both sides of the lead.

43. The semiconductor chip package according to claim 40, wherein the bent portion is entirely within the thinned portion.

44. The semiconductor chip package according to claim 40, wherein the lead is only thinned within the bent portion.

45. The semiconductor chip package according to claim 40, wherein the lead comprises a bend in a first direction and a bend in a second direction, such that the lead frame defines a down set region adapted to accommodate the chip.

46. The semiconductor chip package according to claim 45, wherein the lead frame is thinned in at least part of the down set region.

47. The semiconductor chip package according to claim 40, wherein the leads do not substantially project beyond the exterior of the chip package.

48. The semiconductor chip package according to claim 40, wherein portions of the lead frame are exposed at the upper surface of the chip package.

49. The semiconductor chip package according to claim 40, comprising a plurality of leads.

50. The semiconductor chip package according to claim 40, comprising two or more chips.

51. The semiconductor chip package according to any claim 40, wherein the or each chip is fully encapsulated by the resin layer.

52. The semiconductor chip package according to claim 40, wherein at least one conductive bump is provided on the upper surface of the or each chip, and the or each lead is in electrical contact with at least one bump, such that the chip is electrically connected to the lead via the bump.

53. The semiconductor chip package according to claim 52, wherein the or each lead is electrically connected to the chip by a plurality of bumps.

54. A method of fabricating a semiconductor chip package, the method comprising:
providing a semiconductor chip;
providing a lead frame comprising at least one lead; and
encapsulating at least part of the semiconductor chip and at least part of the lead frame within an encapsulating layer;
wherein the lead comprises a first portion having a first thickness and defining a lead frame pad at least partially exposed at an exterior surface of the package and a second portion extending from the first portion towards the semiconductor chip and electrically connecting a surface portion of the semiconductor chip to the lead frame pad, and wherein the method further comprises:
thinning at least part of the second portion to form a thinned portion such that the thinned portion is thinner than the first portion; and
bending at least part of the thinned portion to form at least part of a bent portion of the second portion of the lead,
wherein the thinned portion extends from the lead pad,
and wherein the junction between the lead pad and the thinned portion forms a step change in the thickness of the lead at the exterior of the package such that the encapsulating layer terminates at the step change adjacent to an exposed part of the lead pad.

55. The method of fabricating a semiconductor chip package according to claim 54, wherein thinning at least part of the second portion forming a thinned portion comprises reducing the thickness of the lead from one side of the lead.

56. The method of fabricating a semiconductor chip package according to claim 54, wherein thinning at least part of the second portion forming a thinned portion comprises reducing the thickness of the lead from both sides of the lead.

57. The method of fabricating a semiconductor chip package according to any claim 54, further comprising only bending the lead within the thinned portion.

58. The method of fabricating a semiconductor chip package according to any claim 54, further comprising only thinning the lead within the bent portion.

59. The method of fabricating a semiconductor chip package according to claim 54, wherein bending at least part of the lead to form a bent portion comprises bending the lead in a first direction and bending the lead in a second direction such that the lead frame defines a down set region adapted to accommodate the chip.

60. The method of fabricating a semiconductor chip package according to claim 54, further comprising thinning the lead frame within at least part of the down set region.

61. The method of fabricating a semiconductor chip package according to claim 54, wherein the leads do not substantially project beyond the exterior of the chip package.

62. The method of fabricating a semiconductor chip package according to claim 54, further comprising exposing portions of the lead frame at the upper surface of the chip package.

63. The method of fabricating a semiconductor chip package according to claim 54, comprising providing a plurality of leads.

64. The method of fabricating a semiconductor chip package according to claim 54, comprising providing two or more chips.

65. The method of fabricating a semiconductor chip package according to claim 54, further comprising encapsulating the or each chip fully within the resin layer.

66. The method of fabricating a semiconductor chip package according to claim 54, further comprising providing at least one conductive bump on the upper surface of the or each chip, such that the or each lead is in electrical contact with at least one bump, thereby electrically connecting the chip to the lead.

67. The method of fabricating a semiconductor chip package according to claim 66, further comprising electrically connecting the or each lead to the chip by a plurality of bumps.

68. The method of fabricating a semiconductor chip package according to claim 54, wherein the step of thinning at least part of the second portion forming a thinned portion comprises partially etching at least part of the second portion to reduce its thickness.
